(19) United States
(12) Patent Application Publication
(10) Pub. No.: US 2008/0302982 A1
(43) Pub. Date: Dec. 11, 2008

(54) POLARIZER ELEMENTS AND SYSTEMS USING THE SAME

(75) Inventors: Jian Wang, Orefield, PA (US); Qihong Wu, Somerset, NJ (US); Paul Sciortino, JR., Bridgewater, NJ (US); Feng Liu, Allentown, PA (US)

Correspondence Address: FISH & RICHARDSON P.C., P.O. BOX 1022, MINNEAPOLIS, MN, 55440-1022, US

(73) Assignee: API Nanofabrication and Research Corp., Somerset, NJ (US)

(21) Appl. No.: 12/106,791

(22) Filed: Apr. 21, 2008

Related U.S. Application Data
(60) Provisional application No. 60/925,728, filed on Apr. 23, 2007.

(51) Int. Cl. G02B 5/20; C23C 16/44; G02B 27/00

(52) U.S. Cl. 250/551; 427/255.28; 359/486

(57) ABSTRACT

In general, in a first aspect, the invention features an article that includes a plurality of spaced apart ridges extending along a first direction, adjacent ridges being spaced with a period of Λ or less, each ridge comprising a plurality of layers where adjacent layers have different refractive indexes at a first wavelength λ₁ and a second wavelength λ₂, where λ₁ and λ₂ are different, Λ<λλ₁, and Λ<λ₂. The ridges are configured so that for radiation at λ₁ and λ₂ incident on the grating, the grating substantially blocks the radiation at λ₁ having a first polarization state, substantially transmits the radiation at λ₂ having the first polarization state, and substantially transmits the radiation at λ₁ and λ₂ having a second polarization state, where the first and second polarization states are orthogonal.

### CROSS REFERENCE TO RELATED APPLICATIONS

Under 35 U.S.C. 119(e)(1), this application claims benefit of U.S. Provisional Application No. 60/925,728, filed on Apr. 23, 2007, the entire contents of which are incorporated herein by reference.

### TECHNICAL FIELD

This disclosure relates to polarizers and to systems that utilize polarizers.

### BACKGROUND

Certain types of polarizers operate by transmitting one polarization state of incident light while reflecting the orthogonal polarization state. This type of polarizer is referred to as a reflective polarizer. Reflective polarizers can be used in a variety of applications, such as for light recycling in liquid crystal displays (LCDs). Reflective polarizers can also be used in optical isolators (also referred to as Faraday isolators), which allows the transmission of light of certain wavelengths in one direction, but not in the opposite direction.

### SUMMARY

In general, in a first aspect, the invention features an article that includes a plurality of spaced apart ridges extending along a first direction, adjacent ridges being spaced with a period of Λ or less, each ridge comprising a plurality of layers where adjacent layers have different refractive indexes at a first wavelength λ₁ and a second wavelength λ₂, where λ₁ and λ₂ are different, Λ<λ₁, and Λ<λ₂. The ridges are configured so that for radiation at λ₁ and λ₂ incident on the grating, the grating substantially blocks (e.g., transmits about 2% or less, about 1% or less, about 0.5% or less, about 0.1% or less, e.g., reflects about 80% or more, about 90% or more, about 93% or more, about 95% or more, about 97% or more, about 98% or more, about 99% or more) the radiation at λ₁ having a first polarization state, substantially transmits (e.g., transmits about 80% or more, about 90% or more, about 95% or more, about 97% or more, about 98% or more, about 99% or more) the radiation at λ₂ having the first polarization state, and substantially transmits (e.g., transmits about 80% or more, about 90% or more, about 95% or more, about 97% or more, about 98% or more, about 99% or more) the radiation at λ₁ and λ₂ having a second polarization state, where the first and second polarization states are orthogonal.

In general, in another aspect, the invention features an article that includes a plurality of spaced apart ridges extending along a first direction, adjacent ridges being spaced with a period of Λ or less, each ridge comprising a plurality of layers where adjacent layers have different refractive indexes at a first wavelength λ₁ and Λ<λ₁. At least some of the plurality of layers have an optical thickness approximately equal to λ₁/4.

In the aforementioned articles, adjacent ridges can define a trench which is filled with a material that is different from at least one of the materials forming the plurality of layers.

In another aspect, the invention features an article that includes a Faraday rotator and an article of the aforementioned aspects, wherein the article of the aforementioned aspects is positioned relative to the Faraday rotator to polarize radiation at λ₁ propagating along a path through the Faraday rotator.

In general, in another aspect, the invention features a method that includes forming a plurality of spaced apart ridges extending along a first direction, adjacent ridges being spaced with a period of Λ or less, each ridge comprising a plurality of layers where adjacent layers have different refractive indexes at a first wavelength λ₁ and Λ<λ₁, wherein at least some of the plurality of layers have an optical thickness approximately equal to λ₁/4 and depositing material between adjacent ridges using atomic layer deposition.

In general, in a further aspect, the invention features an optical isolator having a polarizer comprising a grating having a period of about A or less, wherein the optical isolator is configured to substantially transmit radiation having a first polarization state at a wavelength λ₁ incident on the optical isolator in a first direction and to substantially block radiation having a second polarization state at wavelength λ₁ incident on the optical isolator in the first direction, wherein the first and second polarization states are orthogonal and Λ<λ₁.

In general, in another aspect, the invention features an optical isolator having an active area of about 500 μm×500 μm or less (e.g., about 400 μm×400 μm or less, about 300 μm×300 μm or less, about 200 μm×200 μm or less).

In general, in another aspect, the invention features a system that includes a light source configured to emit radiation at λ₁, a detector, a wavelength division multiplexer (WDM) configured to direct radiation emitted from the light source along an optical path to an optical fiber and to direct radiation from the optical fiber to the detector, and an optical isolator positioned in the optical path between the WDM and the optical fiber.

In general, in a further aspect, the invention features a system that includes a light source configured to emit radiation at λ₁, a detector, and an optical isolator comprising the article according to one of the aforementioned aspects, wherein the system is configured to receive input radiation from an optical fiber and direct the input radiation to the detector, and further configured to direct output radiation at λ₁ from the light source to the optical fiber, where the paths of both the input radiation and the output radiation traverse the optical isolator.

Among other advantages, embodiments include wavelength dependent polarizers that can be adapted for use at specific wavelengths. For example, polarizers can be tailored to polarize radiation at specific wavelengths used in optical communications networks, while transmitting unpolarized radiation certain other wavelengths used in optical communications networks.

Wavelength dependent polarizers can be used in optical isolators. The optical isolators can be wavelength dependent because the polarizers are wavelength dependent. As a result, the optical isolators can be used in optical communications networks that utilize multiple wavelengths to isolate a subset of the wavelengths, while not interfering with the other wavelengths. The optical isolators can be positioned at the tip of a fiber which carries signals at the multiple wavelengths. The isolators then allows one or more wavelengths to pass through bi-directionally, but allows other wavelengths through in one direction only and blocks the passage of radiation at these wavelengths in the other direction.

Optical isolators can be made relatively small. Since the light beam at fiber tip is often only ˜100 μm or less in diameter, small (e.g., ˜200 μm×200 μm in entrance and exit surface area) isolators can be used. This can significantly save the material usage for making the isolator and therefore lead to low cost isolators. Small isolators can also reduce the overall size of the systems that utilize the isolators, such as the size of optical network units (e.g., transceiver units).

The details of one or more embodiments are set forth in the accompanying drawings and the description below. Other features and advantages will be apparent from the description, drawings, and claims.

### DESCRIPTION OF DRAWINGS

FIG. 1 is a schematic diagram of an embodiment of a polarizer element.

FIGS. 2A and 2B are cross-sectional and plan views, respectively, of an embodiment of a polarizer element.

FIG. 3A is a transmission spectrum of a periodic multilayer structure.

FIG. 3B are schematic plots showing transmission spectra of a polarizer element for different polarization states.

FIG. 4 is a schematic diagram of an embodiment of an optical isolator.

FIG. 5A is a schematic diagram of an embodiment of an optical network unit.

FIG. 5B is a perspective view of an optical isolator in an optical network unit.

FIG. 6 is a schematic diagram of an optical communications network.

Like reference symbols in the various drawings indicate like elements.

### DETAILED DESCRIPTION

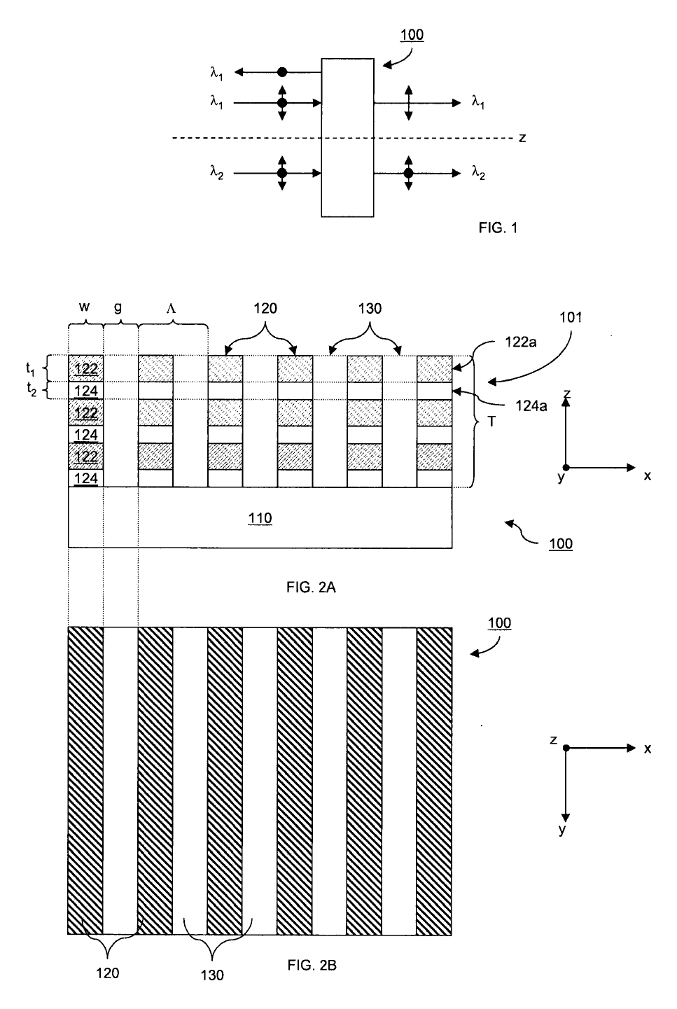

FIG. 1 shows a polarizer element that polarizes incident radiation at a first wavelength, λ₁, substantially transmitting radiation linearly polarized in the plane of FIG. 1 propagating along the z-direction (e.g., normally-incident s-polarized radiation), while substantially blocking radiation linearly polarized orthogonal to the plane of FIG. 1 propagating along the z-direction (e.g., normally-incident p-polarized radiation). The normally incident s-polarized radiation is considered to be polarized parallel to the transmission axis of the polarizer element. Polarizer element 100 substantially transmits both polarization states of incident radiation at a second wavelength λ₂ propagating along the z-direction, where λ₁ and λ₂ are different.

As used herein, substantially transmitting refers to an insertion loss of less than 1 dB (e.g., 0.8 dB or less, 0.6 dB or less, 0.5 dB or less, 0.4 dB or less, 0.3 dB or less, 0.2 dB or less, 0.1 dB or less, 0.05 dB or less) for incident radiation propagating along the z-direction transmitted by polarizer element 100. Substantially blocking refers to an insertion loss of 3 dB or more (e.g., 5 dB or more, 8 dB or more, 10 dB or more, 12 dB or more, 15 dB or more, 20 dB or more, 30 dB or more) for incident radiation propagating along the z-direction transmitted by polarizer element 100. Insertion loss is given by the equation:

Insertion Loss (dB)=10 log₁₀(Iᵢ/Iₜ),

where Iᵢ and Iₜ refer respectively to the incident and transmitted radiation intensities for a particular polarization state and wavelength.

In general, λ₁ and λ₂ can vary as desired based on the structure and composition of grating layer 101, as discussed below. In certain embodiments, λ₁ and λ₂ are in the infrared portion of the electromagnetic spectrum. For example, λ₁ and λ₂ can be in a range from about 900 nm to about 2,000 nm (e.g., in a ranged from about 1,300 nm to about 1,600 nm). As mentioned above, λ₁ and λ₂ are different. In some embodiments, |λ₁−λ₂| is about 30 nm or more (e.g., about 40 nm or more, about 50 nm or more, about 60 nm or more, about 80 nm or more, about 100 nm or more, about 150 nm or more, about 200 nm or more, about 300 nm or more).

In embodiments, λ₁ and λ₂ correspond to wavelengths associated with optical communications networks. For example, λ₁ can be about 1,310 nm±50 nm and λ₁ can be 1,490 nm±10 nm. Alternatively, λ₂ can be about 1,310 nm±50 nm and λ₁ can be 1,490 nm±10 nm. As another example, λ₁ can be about 1,310 nm±50 nm and λ₂ can be 1,550 nm 110 nm, or λ₁ can be about 1,310 nm±50 nm and λ₂ can be 1,550 nm±10 nm.

In some embodiments, polarizer elements can be designed for use at a third wavelength, λ₃, in addition to λ₁ and λ₂. Polarizer elements can be designed to polarize radiation at λ₁, while substantially transmitting radiation at λ₂ and λ₃. Alternatively, polarizer elements can be designed to polarize radiation at λ₁ and λ₃, while substantially transmitting radiation at λ₂. As an example, a polarizer element can be designed to meet certain performance standards at 1,310±50 nm, 1,490±10 nm, and 1,550±10 nm. In certain embodiments, for example, polarizer elements can be designed to polarize radiation at 1,310±50 nm, while substantially transmitting radiation at 1,490±10 nm, and 1,550±10 nm.

Referring to FIGS. 2A and 2B, which shows polarizer element 100 in more detail, polarizer element 100 includes a grating layer 101 that is supported by a substrate 110. Grating layer 101 includes a number of parallel ridges 120 that extend along the y-direction. Ridges 120 have a width w in the x-direction. Gaps 130 have a width g in the x-direction. Ridges 120 form a grating having a period Λ, where Λ=w+g. Λ is less than both λ₁ and λ₂. For example, Λ can be about 0.5λ₁ or less (e.g., about 0.4 λ₁ or less, about 0.3λ₁ or less, about 0.2λ₁ or less, about 0.1λ₁ or less). Accordingly, grating layer 101 is form birefringent for radiation at λ₁ and λ₂, and the effective refractive index of grating layer 101 is different for p-polarized radiation and s-polarized radiation. Λ can be about 2,000 nm or less (e.g., about 1,500 nm or less, about 1,000 nm or less, about 800 nm or less, about 600 nm or less, about 500 nm or less, about 400 nm or less, about 300 nm or less, about 200 nm or less)

In general, w can vary. w can be about 0.75 Λ or less (e.g., about 0.6 Λ or less, about 0.5 Λ or less, about 0.4 Λ or less, about 0.3 Λ or less). w can be about 1,500 nm or less (e.g., about 1,000 mm or less, about 750 nm or less, about 500 nm or less, about 400 nm or less, about 300 nm or less, about 200 nm or less, about 100 nm or less, about 75 nm or less).

In some embodiments, Λ is about 500 nm and w is about 250 nm. In certain embodiments, Λ is about 400 nm and w is about 200 nm.

While each ridge 120 in polarizer element 100 has a rectangular cross-sectional profile, in general, ridges can have other profiles. For example, ridges can have trapezoidal, triangular, curved, or irregular profiles.

Each ridge 120 is composed of a number of alternating layers of having relatively low and high refractive index, n₁ and n₂, respectively, at λ₁. These layers are indicated by reference numerals 122 and 124, respectively, where layers 122 have a thickness t₁ and layers 124 have a thickness t₂ as measured along the z-direction. Each pair of adjacent high and low index layers is referred to as a bilayer. Accordingly, ridges 120 are each composed of a plurality of bilayers, forming a stratified periodic medium.

While ridges 120 are depicted as including 3 bilayers, in general, the number of bilayers in a portion can vary as desired. Typically, the number of bilayers will be selected based on the desired blocking characteristics of the grating layer. In embodiments, ridges 120 can include 4 or more bilayers (e.g., 5 or more, 8 or more, 10 or more, 12 or more, 15 or more, 20 or more bilayers).

Layers 122 and 124 can be formed from a variety of materials. Typically, layers 122 and 124 are formed from dielectric materials and/or semiconductor materials. Examples of dielectric materials include dielectric oxides (e.g., metal oxides), fluorides (e.g., metal fluorides), sulphides, and/or nitrides (e.g., metal nitrides). Examples of oxides include SiO₂, Al₂O₃, Nb₂O₅, TiO₂, ZrO₂, HfO₂, SnO₂, ZnO, ErO₂, Sc₂O₃, and Ta₂O₅. Examples of fluorides include MgF₂. Other examples include ZnS, SiNₓ, SiO_{y}Nₓ, AlN, TiN, and HfN. Semiconductor materials that can be used include silicon (e.g., crystalline, poly-crystalline, or amorphous silicon), Ge, GaP, InP, and InGaAs.

As an example, in some embodiments, polarizer element 100 has a grating layer that includes 4½ bilayers each including a layer of Si and a layer of SiO₂. The substrate is glass. The thickness of the layers in each ridge of the grating layer, starting with the layer closest to the glass, is as follows: 85 nm Si; 200 nm n SiO₂; 80 nm Si; 250 nm SiO₂; 80 nm Si; 250 nm SiO₂; 85 nm Si; 200 nm SiO₂; 70 nm Si. The total thickness, T, of the ridges is 1.3 μm. The period, Λ, is about 500 nm, and the width of each ridge, w, is about 250 nm.

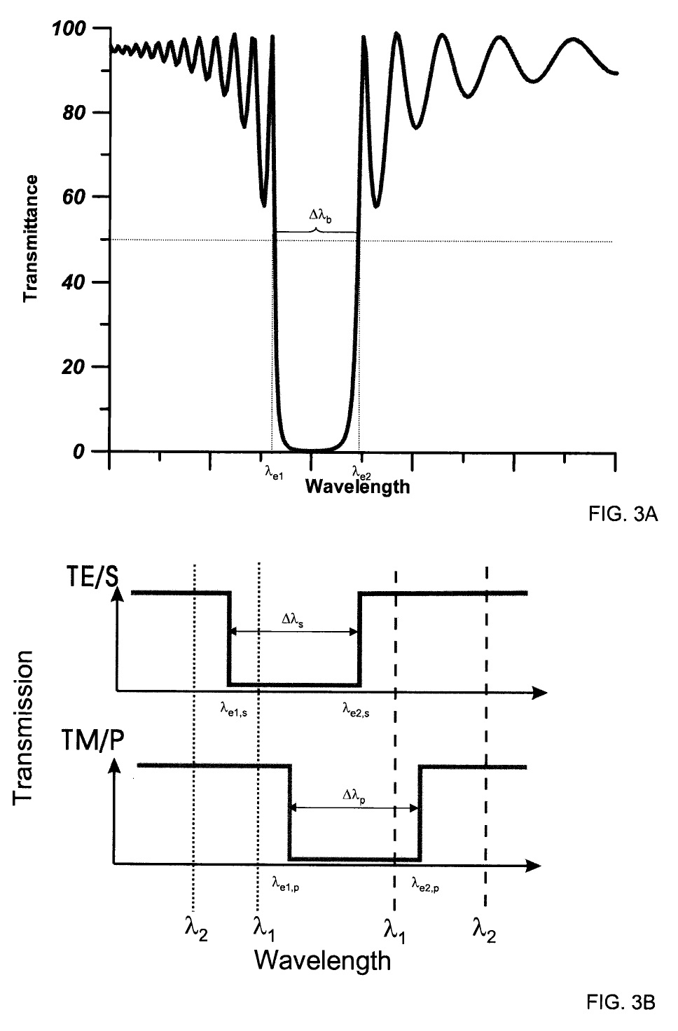

Each layer 122 and 124 has an optical thickness n₁t₁ and n₂t₂, respectively. The optical thickness of layers 122 and 124 can be the same. For wavelengths at or near one-quarter of the optical thickness of layers 122 and 124, reflections from each interface between layers 122 and 124 constructively interfere, resulting in a strong reflection of incident radiation at these wavelengths. Referring to FIG. 3A, the transmission characteristics of a stratified period medium include a band of wavelengths, Δλ_{b}, for which incident radiation is substantially blocked (e.g., reflected). At least 50% of radiation normally incident on the stratified period medium is blocked for these wavelengths. For certain wavelengths within Δλ_{b}, at least 90% (e.g., 92% or more, 95% or more, 98% or more) of radiation normally incident on the stratified period medium is blocked. The edges of the blocked wavelength band, Δλ_{b}, are defined as the wavelengths at which 50% of radiation normally incident on the stratified period medium is blocked. These wavelengths are indicated as λₑ₁ and λₑ₂ in FIG. 3A.

In general, λₑ₁ and λₑ₂ depend on the thicknesses, t₁ and t₂, and refractive indexes n₁ and n₂ or layers 122 and 124. Typically, where n₁t₁ and n₂t₂ are equal, the center wavelength of the blocked wavelength band, λ_{c}=(λₑ₁+λₑ₂)/2, is approximately equal to 4n₁t₁. In other words, the position of the band edges can be determined based on the optical thickness of layers 122 and 124. Also, the reflectance of the stratified periodic medium at λ_{c} depends on the number of bilayers 122 and 124 composing ridges 120. Typically, more layers results in a stronger reflection at λ_{c}. Accordingly, the number of layers can be selected to provide desired reflectance at λ_{c}. Furthermore, the bandwidth Δλ_{b} of the blocked wavelength band depends on the difference between n₁ and n₂. Typically, the larger the refractive index mismatch, Δn=|n₁−n₂|, the larger Δλ_{b} is. As a result, the composition of layers 122 and 124 can be selected to provide a Δn value corresponding to a desired block wavelength bandwidth. Note that Δλ_{b} can also be increased by varying the optical thickness of certain layers, so that not all bilayers have the same period. In some embodiments, Δλ_{b} is about 10 nm or more (e.g., about 20 nm or more, about 30 nm or more, about 40 nm or more, about 50 nm or more, about 75 nm or more, about 100 nm or more).

Grating layer 101 can be considered to be composed of a plurality of sub-grating layers, e.g., 122a and 124a, where each sub-grating layer is composed of parallel ridges formed from corresponding layers 122 and 124 in each ridge 120. As each sub-grating layer has a period Λ, each sub-grating layer is form birefringent for radiation at λ₁ and λ₂.

Without wishing to be bound by theory, the effective refractive index for p-polarized radiation incident along the z-axis corresponds to an ordinary refractive index, nₒ, for each sub-grating layer. The effective refractive index for s-polarized radiation incident along the z-axis corresponds to an extraordinary refractive index, nₑ, for each sub-grating layer. Ordinary and extraordinary index for each retardation layer can be determined according to the equations:

$${n}_{o}^{2} = \frac{w}{Λ} {n}_{120}^{2} + \frac{g}{Λ} {n}_{130}^{2}$$

$$\frac{1}{{n}_{e}^{2}} = \frac{w}{Λ} \frac{1}{{n}_{120}^{2}} + \frac{g}{Λ} \frac{1}{{n}_{130}^{2}}$$

where n₁₂₀ corresponds to n₁ for sub-grating layer 122a and to n₂ for sub-grating layer 124a. n₁₃₀ corresponds to the refractive index of the medium in gaps 130, which, for air, is approximately 1.

Because the effective refractive indexes for orthogonal polarization states are different, the band of wavelengths blocked by the stratified periodic medium will be different for the orthogonal polarization states. In other words, with reference to FIG. 3B, grating 101 blocks radiation of a first band of wavelengths Δλₚ for normally-incident p-polarized radiation and blocks radiation of a second band of wavelengths Δλₛ for the normally-incident s-polarized radiation, where Δλₚ and Δλₛ are different. Correspondingly, λₑ₁ for s-polarized radiation, designated λ_{e1,s}, is different than λₑ₁ for p-polarized radiation (λ_{e1,p}), and λₑ₂ for s-polarized radiation, designated λ_{e2,s}, is different than λₑ₂ for p-polarized radiation (λ_{e2,p}).

Accordingly, there are at least some wavelengths in wavelength band Δλₚ that are not in wavelength band Δλₛ. In some embodiments, λ₁ lies within Δλₛ but outside of Δλₚ. Accordingly, the multilayer structure of grating layer 101 substantially blocks incident s-polarized radiation at λ₁, but substantially transmits p-polarized radiation at λ₁. In contrast, λ₂ lies outside both Δλₚ and Δλₛ. As a result, grating 101 substantially transmits both p- and s-polarization states at λ₂. This situation is shown by wavelengths λ₁ and λ₂ on the left hand side of FIG. 3B. Here, λ₂<λ_{e1,s}<λ₁<λ_{e1,p}.

In other embodiments, however, λ₁ lies within Δλₚ but outside of Δλₛ.

Accordingly, in this arrangement, the multilayer structure of grating layer 101 substantially blocks incident p-polarized radiation at λ₁, but substantially transmits s-polarized radiation at λ₁. In contrast, λ₂ lies outside both Δλₚ and Δλₛ. As a result, grating 101 substantially transmits both p- and s-polarization states at λ₂. This situation is shown on the right hand side of FIG. 3B. Here, λ_{e2,s}<λ₁<λ_{e2,p}<λ₂.

In embodiments, λ_{e1,s} and/or λ_{e1,p} can be in a range from about 400 nm to about 2,000 nm (e.g., about 700 nm to about 1,600 nm, about 900 nm to about 1,100 nm, about 1,300 nm to about 1,600 nm). λ_{e1,s} and/or λ_{e1,p} can be about 700 nm or more (e.g., about 800 nm or more, about 900 nm or more, about 1,000 nm or more, about 1,100 nm or more, about 1,200 nm or more, about 1,300 nm or more, about 1,400 or more, about 1,500 nm or more). λ_{e1,s} and/or λ_{e1,p} can be about 2,000 nm or less, about 1,900 nm or less, about 1,800 nm or less, about 1,700 nm or less, about 1,600 nm or less, about 1,500 nm or less).

λ_{e2,s} and/or λ_{e2,p} can be in a range from about 400 nm to about 2,000 nm (e.g., about 700 nm to about 1,600 nm, about 900 nm to about 1,100 nm, about 1,300 nm to about 1,600 nm). λ_{e2,s} and/or λ_{e2,p} can be about 700 nm or more (e.g., about 800 nm or more, about 900 nm or more, about 1,000 nm or more, about 1,100 nm or more, about 1,200 nm or more, about 1,300 nm or more, about 1,400 or more, about 1,500 nm or more). λ_{e2,s} and/or λ_{e2,p} can be about 2,000 nm or less, about 1,900 nm or less, about 1,800 nm or less, about 1,700 nm or less, about 1,600 nm or less, about 1,500 nm or less).

in general, substrate 110 provides mechanical support to polarizer element 100. Substrate 110 can be formed from a material that is transparent to light at the operational wavelengths λ₁ and λ₂, transmitting substantially all light impinging thereon at these wavelengths (e.g., about 90% or more, about 95% or more, about 97% or more, about 99% or more, about 99.5% or more).

In general, substrate 110 can be formed from any material compatible with the manufacturing processes used to produce polarizer element 100 that can support grating layer 101 and have the desired optical properties (e.g., transparency). In certain embodiments, substrate 110 is formed from a glass, such as BK7 (available from Abrisa Corporation), borosilicate glass (e.g., pyrex available from Corning), aluminosilicate glass (e.g., C1737 available from Corning), or quartz/fused silica. In some embodiments, substrate 10 can be formed from a crystalline material, such as a non-linear optical crystal (e.g., LiNbO₃ or a magneto-optical rotator, such as garnet) or a crystalline (or semicrystalline) semiconductor (e.g., Si, InP, or GaAs). Substrate 110 can also be formed from an inorganic material, such as a polymer (e.g., a plastic).

In general, polarizer element 100 can be formed using a variety of techniques. For example, polarizer element 100 can be formed using techniques commonly used to form optical components and/or integrated circuits, including various deposition techniques and patterning techniques. Deposition techniques include evaporation techniques, sputtering techniques, vapor deposition techniques, and/or atomic layer deposition. Patterning techniques include lithography techniques, such as photolithography, e-beam lithography, imprint lithography etc.

In some embodiments, gaps 130 can be filled with a material providing a monolithic grating layer. The material used to fill gaps 130 should have a different refractive index relative to at least one of materials used to form layers 122 and 124. Gaps 130 can be filled using a variety of deposition methods, such as coating, vapor deposition (e.g., chemical vapor deposition or physical vapor deposition), evaporation, sputtering or atomic layer deposition.

In general, polarizer elements can include additional portions in addition to those described above with respect to polarizer element 100. For example, polarizer elements can include one or more additional layers, such as protective coatings (e.g., on top of grating layer 101), anti-reflection coatings (e.g., on top of grating layer 101, on top of a protective coating on top of grating layer 101, and/or on the surface of the substrate opposite grating layer 101). As another example, In some embodiments, polarizer elements are integrated onto additional optical elements, such as non-linear optical elements, electro-optic elements, and/or magneto-optic elements.

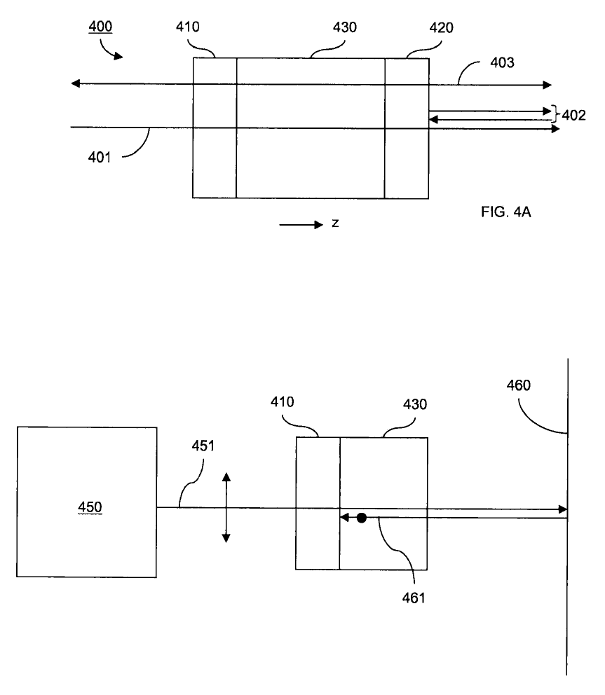

Polarizer elements, such as polarizer element 100, can be used in a variety of applications. For example, in some embodiments, polarizer elements are used in an optical isolator. An example of an optical isolator 400 is shown in FIG. 4. Isolator 400 includes polarizer elements 410 and 420 which are positioned on opposite ends of an optical rotator element 430. Commonly, optical rotator element 430 is Faraday rotator which, by virtue of a magneto-optic effect known as the Faraday effect, rotates the plane of polarization of linearly polarized radiation propagating through the element.

The transmission axis of polarizer 410 is rotated by 45° about the z-axis with respect to the transmission axis of polarizer 420. The transmission axes of polarizers 410 and 420 and rotator element 430 are configured relative to each other so that isolator 400 transmits incident radiation at λ₁ propagating parallel to the z-axis in one direction, the pass direction (i.e., propagating from left to right in FIG. 4), but not in the opposite direction, the block direction (i.e., propagating from right to left in FIG. 4).

For radiation at λ₁ incident on isolator 400 propagating in the pass direction (indicated as ray 401), polarizer 410 transmits substantially linearly polarized radiation, which is rotated by 45° with respect to the z-axis as it propagates through rotator element 430. At polarizer 420, this radiation is now polarized parallel to the transmission axis of polarizer 420 and is substantially transmitted therethrough, exiting isolator 400.

On the other hand, for radiation at λ₁ incident on isolator 400 propagating in the block direction (indicated by rays 402), polarizer 420 transmits substantially linearly polarized radiation plane polarized along the transmission axis of polarizer 420. This radiation is rotated by 45° with respect to the z-axis as it propagates through rotator element 430. The rotation is in the same direction as the rotation of radiation propagating in the opposite direction. Accordingly, at polarizer element 410, the 45° rotation of the radiation propagating in the block direction results in the radiation being polarized orthogonal to the transmission axis of the polarizer element. Accordingly, this radiation is substantially blocked by polarizer element 410, and does not exit isolator 400 propagating in the block direction.

On the other hand, both polarizers 410 and 420 substantially transmit s- and p-polarized radiation at λ₂. Accordingly, isolator 400 substantially transmits incident radiation at λ₂ propagating along the z-axis in both the pass or block directions (indicated by ray 403).

In general, optical rotator element 430 can be formed from a variety of materials. Where optical rotator element 430 is a Faraday rotator, the rotator element can have a high Verdet constant, low absorption coefficient, low non-linear refractive index and high damage threshold at the operational wavelengths (e.g., at λ₁ and λ₂). Also, to reduce self-focusing and other thermal related effects, the radiation path through the element should be as short as possible.

In some embodiments, the optical rotator element is formed from yttrium iron garnet (YIG) crystals. YIG crystals are suitable materials for use where the operational wavelengths are in the 1,300 nm-1,600 nm range. Other examples of materials that can be used are terbium doped borosillicate glass and terbium gallium garnet crystal (TGG), which can be used where the operational wavelengths are in the 700 nm-1,100 nm range.

While optical isolator 400 includes two polarizer elements, in some embodiments, optical isolator elements can include only a single polarizer element. For example, in certain embodiments, optical isolator does not include polarizer element 420. Such optical isolators can be used where the radiation at λ₁ is substantially prepolarized. For example, where the optical isolator is used in conjunction with a polarized light source (e.g., a laser), an isolator with a single polarizer element can be used to reduce (e.g., prevent) reflection of the laser emission back into the laser cavity. Referring to FIG. 4B, for example, an isolator including polarizer element 410 and optical rotation element 430 can be positioned between a polarized light source 450 and an optical interface 460. Polarizer element 410 is oriented with its transmission axis parallel to the polarization of radiation 451 at λ₁ emitted from source 450. This radiation is substantially transmitted by polarizer element 410 and is rotated by 45° as it propagates through optical rotation element 430. A portion of the radiation 461 reflects from interface 460 back towards source 450. This radiation is rotated a further 45° as it propagates through optical rotation element 430 and is polarized orthogonal to the transmission axis of polarizer element 410 when it reaches the polarizer element. Accordingly, the reflected radiation at λ₁ is blocked from returning to source 450.

Optical isolators, such as isolator 400, can be used in optical communications networks. For example, optical isolators can be used in conjunction with an optical network unit (ONU). Typically, ONUs are used as a terminal for optical signals, e.g., at a user's residence or place of business. In this way, ONUs serve to convert optical signals to electrical signals which are then transmitted to, e.g., telephones, televisions, computers, or further relay equipment, such as routers. ONUs can also be used to launch optical signals into an optical communication networks (e.g., providing information from a user's residence or place of business to a service provider's facility.

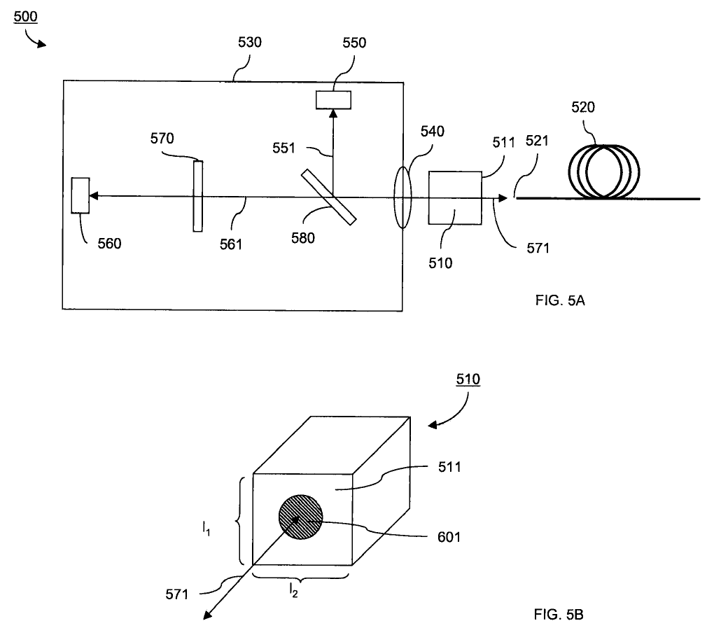

Referring to FIG. 5, a portion of an optical communications network includes an ONU 500, an optical isolator 510, and an optical fiber 520.

ONU 500 includes a detector 550, a laser diode 560, a cut filter 570, a wavelength division multiplex (WDM) filter 580, and a lens 540. These components are contained in a housing 530.

During operation, ONU 500 receives optical signals from fiber 520 and directs outgoing optical signals from laser diode 560 to fiber 520. Laser diode 560 provides radiation 561 at wavelength l1, which is modulated with the outgoing signals. Radiation 561 is transmitted by cut filter 570, is transmitted by WDM filter 580, and is coupled by lens 540 into an end 521 of fiber 520.

Incoming signals are provided by a modulated beam of radiation at 12, which exits end 521 of fiber 520, is collimated by lens 540, and directed by WDM filter 580 onto detector 550. This radiation is indicated by 551.

Optical isolator 510 is positioned between end 521 of fiber and lens 540. As discussed with respect to FIG. 4 above, optical isolator 510 is configured to transmit radiation at λ₁ in one direction only, namely radiation propagating from laser diode 560 to fiber 520. Radiation at λ₁ propagating in the opposite direction is blocked by optical isolator 510. Radiation at λ₂, on the other hand, is transmitted in both directions by optical isolator 510. In this way, optical isolator 510 reduces the potentially adverse interaction of radiation at λ₁ reflected by end 521 of fiber 520 with laser diode 560, without substantially affecting the transmission of incoming optical signals at λ₂.

Optical isolator 510 can be positioned close to end 521 of fiber 520. For example, surface 511 can be position about 1 cm or less (e.g., 5 mm or less, 3 mm or less, 2 mm or less, 1 mm or less, 0.5 mm or less) from end 521. Because beam 571 has a relatively small cross-sectional area close to end 521, optical isolator 510 can have a relatively small active cross sectional area. Referring to FIG. 5B, the active cross-sectional area refers to an area 601 of isolator surface 511 that is illuminated by the radiation being coupled in and out of end 521 of fiber 520. The area of surface 511, given by l₁×l₂, can be 2 mm×2 mm or less (e.g., 1 mm×1 mm or less, 0.5 mm×0.5 mm or less, 0.3 mm×0.3 mm or less, 0.2 mm×0.2 mm or less, 0.1 mm×0.1 mm or less).

Active area 61 can be smaller than the cross-sectional area of beam 561 and/or 551. For example, active area 61 can be about 0.5 times or less (e.g., 0.1 times or less, 0.05 times or less, 0.01 times or less) the cross-sectional area of beam 561 and/or 551.

While ONUs that include optical isolators have been described, optical isolators can be used in other components of optical communications systems. For example, optical isolators can be used in an optical line termination (OLT), which is typically positioned at a service provider's facility. In embodiments, optical isolators in an OLT can reduce (e.g., prevent) transmission of radiation at 1,490±10 nm in one direction, while allowing transmission of radiation at 1,310±50 nm in both directions, for example.

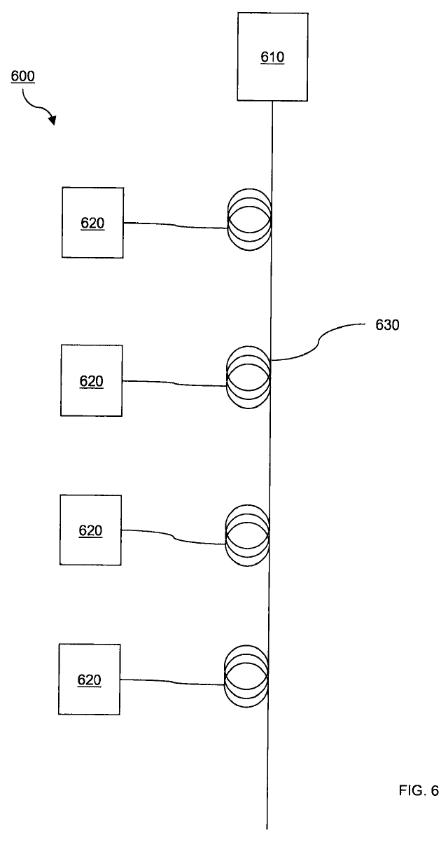

Optical communications networks generally include numerous ONUs and/or OLTs connected via lengths of optical fiber. For example, referring to FIG. 6, an optical communications network 600 includes an OLT 610 and ONUs 620. OLT sends optical signals to the ONUs via fiber network 630, and receives optical signals from the ONUs via the same fiber network.

Other embodiments are in the claims.

What is claimed is:

1. An article, comprising:
a plurality of spaced apart ridges extending along a first direction, adjacent ridges being spaced with a period of Λ or less, each ridge comprising a plurality of layers where adjacent layers have different refractive indexes at a first wavelength λ₁ and a second wavelength λ₂, where λ₁ and λ₂ are different, Λ<λ₁, and Λ<λ₂,
wherein the ridges are configured so that for radiation at λ₁ and λ₂ incident on the grating, the grating substantially blocks the radiation at λ₁ having a first polarization state, substantially transmits the radiation at λ₂ having the first polarization state, and substantially transmits the radiation at λ₁ and λ₂ having a second polarization state, where the first and second polarization states are orthogonal.

2. An article, comprising:
a plurality of spaced apart ridges extending along a first direction, adjacent ridges being spaced with a period of Λ or less, each ridge comprising a plurality of layers where adjacent layers have different refractive indexes at a first wavelength λ₁ and Λ<λ₁,
wherein at least some of the plurality of layers have an optical thickness approximately equal to λ₁/4.

3. The article of claim 1, wherein adjacent ridges define a trench which is filled with a material that is different from at least one of the materials forming the plurality of layers.

4. An article, comprising:
a Faraday rotator; and
an article according to claims 1,
wherein the article is positioned relative to the Faraday rotator to polarize radiation at λ₁ propagating along a path through the Faraday rotator.

5. A method, comprising:
forming a plurality of spaced apart ridges extending along a first direction, adjacent ridges being spaced with a period of Λ or less, each ridge comprising a plurality of layers where adjacent layers have different refractive indexes at a first wavelength λ₁ and Λ<λ₁, wherein at least some of the plurality of layers have an optical thickness approximately equal to λ₁/4; and
depositing material between adjacent ridges using atomic layer deposition.

6. An optical isolator having a polarizer comprising a grating having a period of about Λ or less, wherein the optical isolator is configured to substantially transmit radiation having a first polarization state at a wavelength λ₁ incident on the optical isolator in a first direction and to substantially block radiation having a second polarization state at wavelength λ₁ incident on the optical isolator in the first direction, wherein the first and second polarization states are orthogonal and Λ<λ₁.

7. An optical isolator having an active area of about 500 μm×500 μm or less.

8. A system, comprising:
a light source configured to emit radiation at λ₁;
a detector;
a wavelength division multiplexer (WDM) configured to direct radiation emitted from the light source along an optical path to an optical fiber and to direct radiation from the optical fiber to the detector; and
an optical isolator positioned in the optical path between the WDM and the optical fiber.

9. A system, comprising:
a light source configured to emit radiation at λ₁;
a detector; and
an optical isolator comprising the article according to claim 4,
wherein the system is configured to receive input radiation from an optical fiber and direct the input radiation to the detector, and further configured to direct output radiation at λ₁ from the light source to the optical fiber, where the paths of both the input radiation and the output radiation traverse the optical isolator.
